(19) United States
(12) Patent Application Publication
(10) Pub. No.: US 2023/0046291 A1
(43) Pub. Date: Feb. 16, 2023

(54) TWO-PHASE IMMERSION COOLING DEVICE WITH IMPROVED CONDENSATION HEAT TRANSFER

(71) Applicant: Fulian Precision Electronics (Tianjin) Co., LTD., Tianjin (CN)

(72) Inventors: Chun Wang, Houston, TX (US); WARM-HORNG YUAN, Houston, TX (US)

(21) Appl. No.: 17/583,400

(22) Filed: Jan. 25, 2022

Related U.S. Application Data
(60) Provisional application No. 63/232,339, filed on Aug. 12, 2021.

(51) Int. Cl. H05K 7/20

(52) U.S. Cl. CPC H05K 7/203; H05K 7/20318; H05K 7/20136; H05K 7/20381; H05K 7/20327

(57) ABSTRACT

A two-phase immersion cooling device includes a box body, a plurality of heating elements, a condenser, a cover body, and at least one fan. The box body includes a plurality of side walls and a bottom wall, the side walls are connected to each other top to bottom, the bottom wall is connected to one end of the side walls, the side walls and the bottom wall jointly form an accommodating cavity, and the accommodating cavity contains coolant. The condenser is received in the accommodating cavity, and is arranged along sidewalls of the tank. An upper cavity surrounded by the condenser is defined. The cover body covers the box body to seal the accommodating cavity, the cover body expands on the box body to expose the accommodating cavity to outside. At least one fan is fixedly disposed on the cover body and is accommodated in the upper cavity.

### TECHNICAL FIELD

The present disclosure relates to temperature control, in particular to a two-phase immersion cooling device for enhancing condensation heat transfer.

### BACKGROUND

With the rapid improvement of power and heat flux density of computer chips, internet of things, batteries of new energy vehicles, electronic devices, home digital electrical equipment, digital medical treatment, chips and electronic devices of edge computing, quantum computing, heating components of mechanical equipment and heating components of electronic equipment, the cooling technology of the heating components has also experienced rapid development from generation to generation. After the continuous development of passive cooling, enhanced air cooling, thermosyphon loop heat pipe cooling, liquid cooling and single-phase immersion cooling technology, two-phase immersion cooling method is one of the most promising and effective server cooling technologies.

The existing two-phase immersion cooling device includes a box as a body, a heating element, a coolant, and a condenser. The element generating heat is contained in the lower part of the box body and immersed in the coolant. The condenser is disposed around the periphery along one or a plurality of inner walls on the upper part of the box body. The condenser is far away from the upper cavity formed for the heating element to pass up and down by one or a plurality of side walls. The coolant absorbs the heat generated by the heating element and is boiled and gasified, thereby cooling the heating element. The coolant vapor rises to the upper part of the box body and condenses on the condenser, and the coolant condensed on the condenser falls back into the coolant under the action of gravity, so as to achieve the effect of cooling the heating element. However, the quantity of coolant which is lost by the existing two-phase immersion cooling device is large.

Therefore, improvement is desired.

### SUMMARY OF THE DISCLOSURE

The present disclosure provides a two-phase immersion cooling device with reduced quantity coolant lost.

The present disclosure provides a two-phase immersion cooling device, wherein the two-phase immersion cooling device includes a box body, a plurality of heating elements, a condenser, a cover body, and at least one fan. The box body includes a plurality of side walls connected to each other top to bottom, and a bottom wall, wherein the bottom wall is connected to one end of each of the plurality of the side walls, the plurality of the side walls and the bottom wall jointly form an accommodating cavity, and bottom of the accommodating cavity being configured to contain coolant. The heating elements are disposed in the accommodating cavity and adapted to be immersed in the coolant. The condenser is disposed along the side walls; wherein the condenser is located above the coolant and the heating elements, the condenser is away from the upper cavity surrounded by the plurality of inner side walls. The cover body covers the box body to seal the accommodating cavity; wherein the cover body is adapted to expand on the box body to expose the accommodating cavity to the external environment. At least one fan is fixedly disposed on the cover body and is accommodated in the upper cavity.

According to an embodiment of the present disclosure, the two-phase immersion cooling device further includes a plurality of fans, and the plurality of fans are uniformly disposed in the upper cavity.

According to an embodiment of the present disclosure, the two-phase immersion cooling device further includes at least one sensor disposed in the accommodating cavity, wherein at least one sensor comprises at least one of a temperature sensor, a humidity sensor, a pressure sensor, and a liquid level sensor, at least one sensor is configured for sensing at least one of vapor temperature, liquid temperature, vapor humidity, vapor pressure, and liquid level height of the coolant, an inlet temperature, an outlet temperature and a flow rate of condenser coolant in the accommodating cavity.

According to an embodiment of the present disclosure, the two-phase immersion cooling device includes a safety valve, wherein the safety valve is disposed on the top of the box body; when vapor pressure in the accommodating cavity is higher than a preset vapor pressure, the safety valve is opened until the vapor pressure in the accommodating cavity is lower than the preset vapor pressure, to ensure that the two-phase immersion cooling device works under safe pressure.

According to an embodiment of the present disclosure, the two-phase immersion cooling device includes a coolant management system, the coolant management system is used to replenish the coolant into the accommodating cavity and filtering impurities in the coolant.

According to an embodiment of the present disclosure, the two-phase immersion cooling device further includes a controller, the controller is electrically connected to at least one fan, at least one temperature sensor, at least one pressure sensor, at least one humidity sensor, at least one condensing controller, at least one flow sensor, at least one liquid level sensor, at least one safety valve controller, at least one coolant management system, at least one alarm, and at least one pressure balance valve controller; when at least one sensor senses vapor temperature in the accommodating cavity is higher than a preset temperature or vapor pressure in the accommodating cavity is higher than a preset pressure, the controller controls and adjusts vapor volume and vapor pressure of at least one fan and inlet temperature and a flow rate of the coolant in the condenser; when a liquid level height of the coolant detected by the liquid level sensor is lower than a preset height, the controller controls the alarm to output an alarm, and controls the coolant management system to replenish the coolant into the accommodating cavity.

According to an embodiment of the present disclosure at least one sensor includes at least one of a temperature sensor, a humidity sensor, a pressure sensor, and a liquid level sensor.

According to an embodiment of the present disclosure, the two-phase immersion cooling device also includes a liquid level sensor disposed on the box body, which is connected to the accommodating cavity and used to detect the liquid level height of the coolant.

According to an embodiment of the present disclosure, the plurality of heating elements includes a server applied to a data center, a battery or an electronic device applied to a new energy vehicle, an electronic chip or a device applied to a home intelligent digital appliance, an electronic chip or an electronic device applied to a digital medical treatment, an electronic chip or electronic device for digital medical treatment, a chip and an electronic device for edge computing, a chip for quantum computing, and a heating components applied to mechanical equipment or electronic equipment.

According to an embodiment of the present disclosure, the two-phase immersion cooling device also includes two double-faced sockets hermetically disposed on the box body.

According to an embodiment of the present disclosure, the two-phase immersion cooling device further includes an extracting valve, wherein the extracting valve is disposed on the box body, the extracting valve is connected to a vacuum device to extract non-condensable vapor in the accommodating cavity.

According to an embodiment of the present disclosure, the two-phase immersion cooling device includes a pressure balance valve, the pressure balance valve is disposed on the box body; when vapor pressure in the accommodating cavity is lower than an atmospheric pressure, the pressure balance valve is opened until the vapor pressure in the accommodating cavity is equal to the atmospheric pressure, to open the box body.

According to an embodiment of the present disclosure, the two-phase immersion cooling device further includes a handle disposed on the cover body.

According to an embodiment of the present disclosure, the two-phase immersion cooling device further includes a supporting member, wherein the supporting member is disposed on a bottom of the box body; the supporting member is a supporting frame or a roller.

The two-phase immersion cooling device provided by the present disclosure contains fans in the cavity formed by the surrounded condenser that is disposed along the side walls, the rotation of the fans pushes the coolant vapor located in the cavity to the condenser around the box body for condensation, the rate of contact between the coolant vapor and the condenser is increased, and the heat transfer effect of the condenser is effectively strengthened. The evaporation rate and condensation rate of the coolant in the box body tend to balance, it reduces the continuous increase of temperature and pressure in the box body caused by an evaporation rate that is higher than the condensation rate, the pressure difference between inside and outside of the box body is reduced, and the leakage loss of expensive coolant vapor is reduced.

### BRIEF DESCRIPTION OF THE DRAWINGS

FIG. 1 is a schematic diagram of a two-phase immersion cooling device according to an embodiment of the present disclosure.

FIG. 2 is a schematic diagram of a cover body of cooling device of FIG. 1 unfolded on the box body.

FIG. 3 is a sectional view along line III-III of FIG. 1.

FIG. 4 is an exploded view of the cover body and the box body of the device of FIG. 1.

FIG. 5 is a schematic diagram of some components of the two-phase immersion cooling device according to an embodiment of the present disclosure.

FIG. 6 is a schematic diagram of a coolant management system according to an embodiment of the present disclosure.

### DETAILED DESCRIPTION

The following description is used to disclose the present disclosure so that those skilled in the art can implement the present disclosure. The preferred embodiments in the following description are only examples, and those skilled in the art can think of other obvious variations. The basic principles of the present disclosure defined in the following description can be applied to other embodiments, modifications, improvements, equivalents, and other technical solutions that do not deviate from the spirit and scope of the present disclosure.

It can be understood that the height of the box body in the present disclosure refers to the vertically-upward direction and perpendicular to the bottom wall of the box body.

Some embodiments of the present disclosure are described in detail below in combination with the accompanying drawings. Without conflict, the following embodiments and features in the embodiments may be combined or can replace each other.

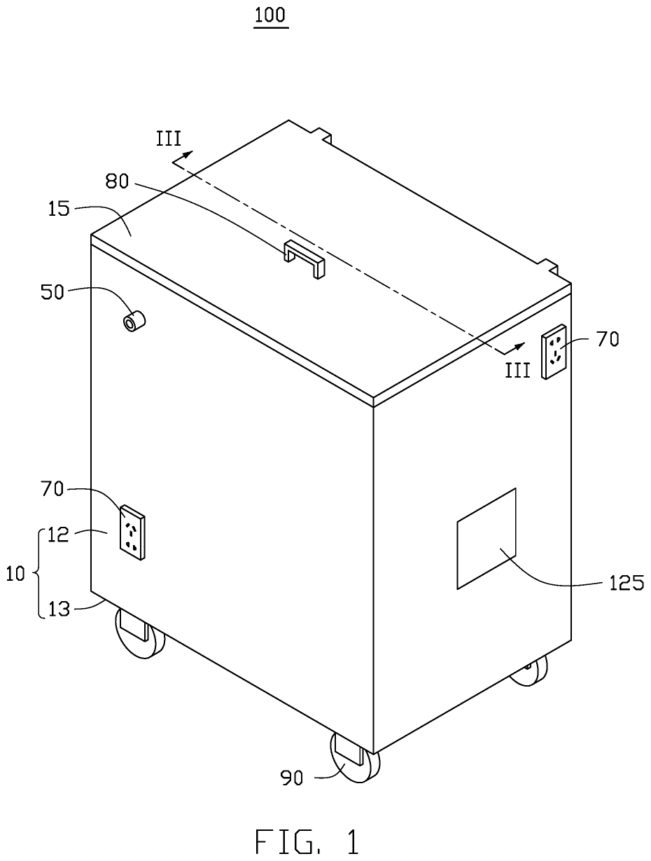

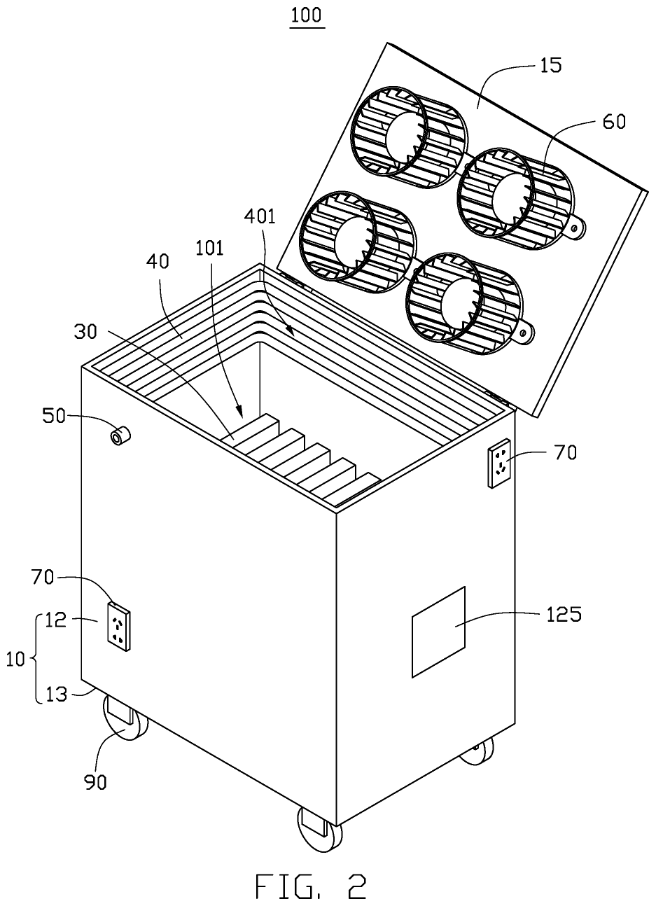

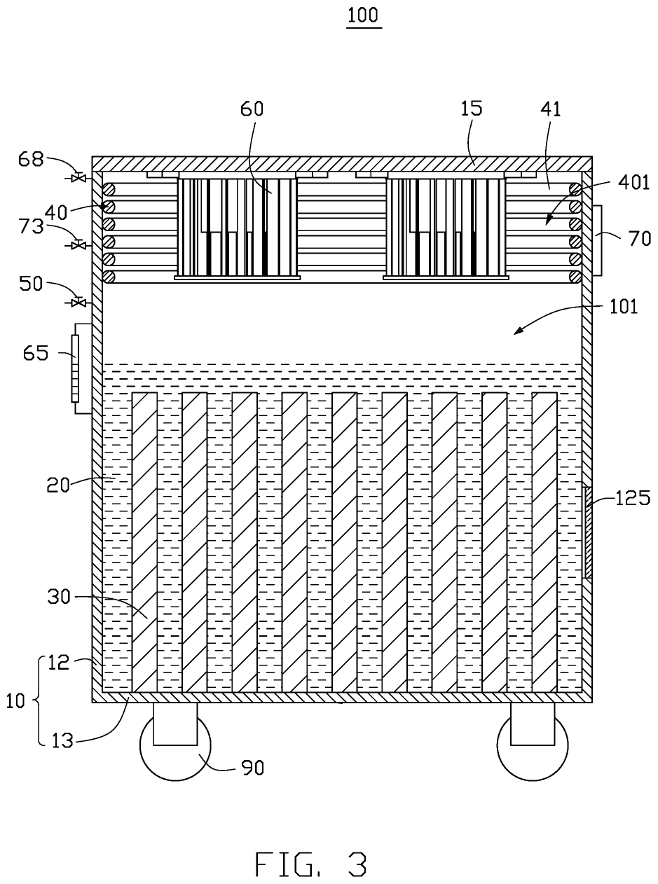

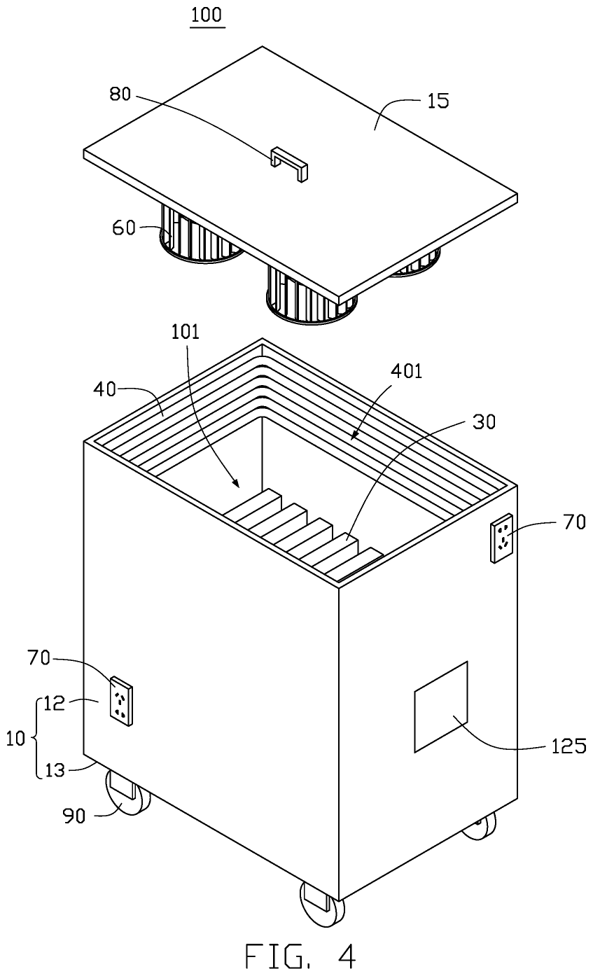

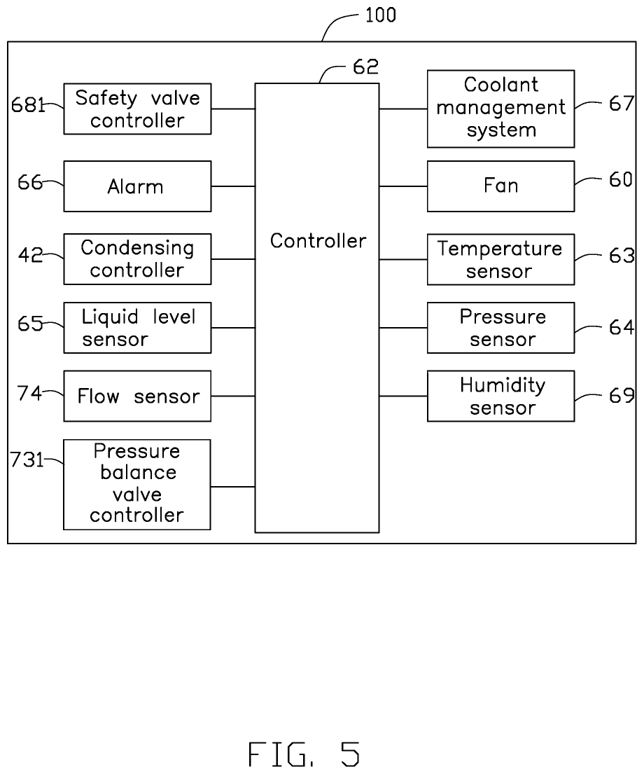

FIG. 1 to FIG. 5 illustrate a two-phase immersion cooling device 100 in accordance with an embodiment of the present disclosure.

The two-phase immersion cooling device 100 includes a box body 10, a cover body 15, a coolant 20, a plurality of heating elements 30, a condenser 40, and at least one fan 60. The box body 10 defines an accommodating cavity 101. The cover body 15 is adapted to cover the box body 10 to seal the accommodating cavity 101, and the cover body 15 can open the box body 10 to expose the accommodating cavity 101 to the outside. The cover body 15 is detachably or reversibly connected to the box body 10. The cover body 15 can be detachably connected to the box body 10 by means of flange connection, hook connection, bite joint connection, clamp connection, screw connection, etc.

The box body 10 includes a plurality of side walls 12 and a bottom wall 13, the side walls 12 are connected from top to bottom, and the bottom wall 13 is connected to bottom ends of the side walls 12. The plurality of the side walls 12 and the bottom wall 13 together form the accommodating cavity 101.

The coolant 20 is disposed in the accommodating cavity 101. The coolant 20 may be, but is not limited to, a liquid having low boiling point and insulating properties. The low boiling point here may be, for example, between about 40-70 degrees or lower than the temperature of the heat generated during the operation of the heating elements 30, in other words, the coolant 20 is a substance suitable for direct contact with the heating elements 30, and can effectively absorb the heat generated by the heating elements 30, and boil and evaporate as a result, the present disclosure is not limited to the coolant 20 and its types and physical characteristics. The coolant 20 boils and gasifies rapidly by absorbing the heat generated by the heating element 30 and reducing the temperature of the heating elements 30 by so doing.

The heating elements 30 are disposed in the accommodating cavity 101 and are immersed in the coolant 20. The heating elements 30 can be, but are not limited to, a server and components applied in a data center, a battery and an electronic device of a new energy vehicle, an electronic chip and device of a home intelligent digital appliance, an electronic chip and an electronic device applied to digital medical treatment, a chip and an electronic device of edge computing, a chip of quantum computing, a chip of a robot, heat-generating components of a mechanical equipment or an electronic equipment. The present disclosure is not limited to the type, quantity, size, or scale of the heating element 30.

The condenser 40 is disposed along the side walls 12. The condenser 40 is accommodated in the accommodating cavity 101 and is located above the coolant 20 and the heating element 30. The condenser 40 is far away from the formed cavity 401 surrounded by surrounds the plurality of the side walls 12. The cavity 401 is used for the heating elements 30 to move up and down during installation, removal, and maintenance. The cavity 401 is part of the accommodating cavity 101. In the embodiment, the condenser 40 includes a plurality of condensing tubes 41, the condensing tube 41 are disposed at intervals on the upper part of the box body 10, and each condensing tube 41 is disposed around the circumference of the upper part of the box body 10. In other embodiments, the condenser 40 may also include only at least one row and one column of the condensing tubes 41. After the coolant 20 is gasified to form coolant vapor, the coolant vapor with high thermal energy flows upward to the condenser 40 in the closed accommodating cavity 101 and condensed on the condenser 40, the condensate is fallen back into the cooling liquid under the action of gravity, so as to achieve the effect of heat dissipation and cooling the heating element.

The fans 60 are fixedly disposed on the cover body 15 and accommodated in the cavity 401. The fans 60 throw the coolant vapor in the cavity 401 to the surrounding condenser 40 for condensation, so that all coolant vapor in the accommodating cavity 101 can be condensed on the surface of the condenser 40, and the coolant vapor flow formed by the fan 60 enhances the heat transfer effect of the condenser 40. In the embodiment, the two-phase immersion cooling device 100 includes four fans 60, fixedly disposed on the cover body 15 and uniformly disposed in the cavity 401, to evenly press the coolant vapor located in the cavity 401 towards the condenser 40 located around the cavity 401. In other embodiments, the number of the fans 60 may be one, two, three, or more than four.

A fan 60 may be, but is not limited to, a squirrel cage fan, an axial fan, a centrifugal fan, a mixed flow fan, a leafless fan, a rotating impeller, etc. The driving motor of the fan 60 can be a cage induction motor or a wound rotor induction motor, a constant speed motor or a speed regulating motor, or a capacitor starting single-phase asynchronous motor or a capacitor running single-phase asynchronous motor. The fan 60 can be started when the heating element 30 is operating and can be closed when the heating element 30 stops operating.

If a fan 60 is not provided in the cavity 401, due to the pressure difference between the coolant vapor located in the cavity 401 and the coolant vapor located at the condenser 40 being very small, only a small part of the coolant vapor located in the cavity 401 would be condensed on the condenser 40 disposed on the box body 10, most of the coolant vapor would remain in the cavity 401 and not be condensed, so that the evaporation rate and condensation rate of the coolant in the box body 10 would not reach equality or equilibrium. With the continuous heating by the heating element 30, after a period of time, the overall temperature in the closed box body 10 gradually increases. The higher the temperature, the greater the pressure in the box body 10. When the pressure in the box body 10 is higher than the pressure outside the box body 10 to form a pressure difference, the vapor in the box body 10 would leak out of the box body 10 under the action of the pressure difference, or from the place where the box body 10 is not tightly sealed, or, in order to prevent the box from exploding, the pressure might be relieved by the safety valve, resulting in the loss of extremely expensive coolant.

In the present disclosure, the fans 60 can be disposed in the cavity 401 to push the coolant vapor located in the cavity 401 to the surrounding condenser 40 for condensation, which increases the contact rate between the coolant vapor and the condenser 40, the heat transfer effect of the condenser 40 is effectively strengthened, so that the evaporation rate and condensation rate of the coolant 20 in the box body 10 tend to balance, the likelihood of a continuous increase of temperature and pressure in the box body 10 caused by an evaporation rate higher than the condensation rate is reduced, the pressure difference inside and outside the box body 10 is reduced, and the leakage loss of expensive coolant vapor is reduced.

The two-phase immersion cooling device 100 further includes a controller 62, a temperature sensor 63, a humidity sensor 69, a plurality of pressure sensors 64, a flow sensor 74, a liquid level sensor 65, a condensing controller 42, a pressure balance valve controller 731, an alarm 66, a safety valve controller 681, and a coolant management system 67.

The temperature sensor 63, the humidity sensor 69 and the pressure sensor 64 are disposed in the accommodating cavity 101 and are respectively used to sense the vapor, liquid temperature, vapor humidity, and vapor pressure at different positions in the accommodating cavity 101. The controller 62 is electrically connected to the fans 60, the temperature sensor 63, the humidity sensor 69, the pressure sensor 64, the flow sensor 74, the liquid level sensor 65, the condensing controller 42, the alarm 66, the safety valve controller 681, and the coolant management system 67. The controller 62 can determine whether there is gaseous coolant in the accommodating cavity 101 according to at least one of the vapor and liquid temperature sensed by the temperature sensor 63, the humidity sensed by the humidity sensor 69 and the vapor pressure sensed by the pressure sensor 64, and it is used to control whether the fans 60 are started or not. When the vapor temperature sensed by the temperature sensor 63 is higher than a preset temperature, or the humidity sensed by the humidity sensor 69 is higher than a preset humidity, or the vapor pressure sensed by the pressure sensor 64 is higher than a preset pressure, the controller 62 controls the fans 60 to start operating.

The controller 62 can also determine whether the condensation amount of the condenser 40 is sufficient according to the heat transfer of the condenser 40, so as to control and adjust the vapor volume and vapor pressure of the fan 60. When the vapor temperature sensed by the temperature sensor 63 is higher than the preset temperature or the humidity sensed by the humidity sensor 69 is higher than the preset humidity or the vapor pressure sensed by the pressure sensor 64 is higher than the preset pressure, the controller 62 controls and adjusts the power of the fans 60. For example, the controller 62 adjusts the rotating speed of the fans 60, so as to adjust the vapor volume and vapor pressure.

The controller 62 is also electrically connected to the condenser 40 through the condensing controller 42, to control the condensation capacity of the condenser 40. When the vapor temperature sensed by the temperature sensor 63 is higher than the preset temperature or the vapor pressure sensed by the pressure sensor 64 is higher than the preset pressure, the controller 62 controls and adjusts the inlet temperature or flow rate of the coolant in the condenser 40.

The two-phase immersion cooling device 100 further includes a safety valve 68. The safety valve 68 is disposed on the box body 10, and the safety valve 68 is electrically connected to the controller 62 through the safety valve controller 681. When the vapor pressure in the accommodating cavity 101 is higher than the preset vapor pressure, the controller 62 is also used to open the safety valve 68, until the vapor pressure in the accommodating cavity 101 is lower than the preset vapor pressure, so as to provide safe operation in the box body 10.

The liquid level sensor 65 is disposed on the side wall 12 of the box body 10, and the liquid level sensor 65 is used to detect the liquid level of the coolant 20. The liquid level sensor 65 is connected to the accommodating cavity 101 using the communicator principle. The liquid level of the coolant 20 in the accommodating cavity 101 can be known by observing the liquid level of the liquid level sensor 65.

The controller 62 can control whether the alarm 66 is activated according to the liquid level of the coolant 20 detected by the liquid level sensor 65. When the liquid level detected by the liquid level sensor 65 is lower than the preset height, the controller 62 controls the alarm 66 to give an alarm and controls the coolant management system 67 to replenish the accommodating cavity 101 with coolant.

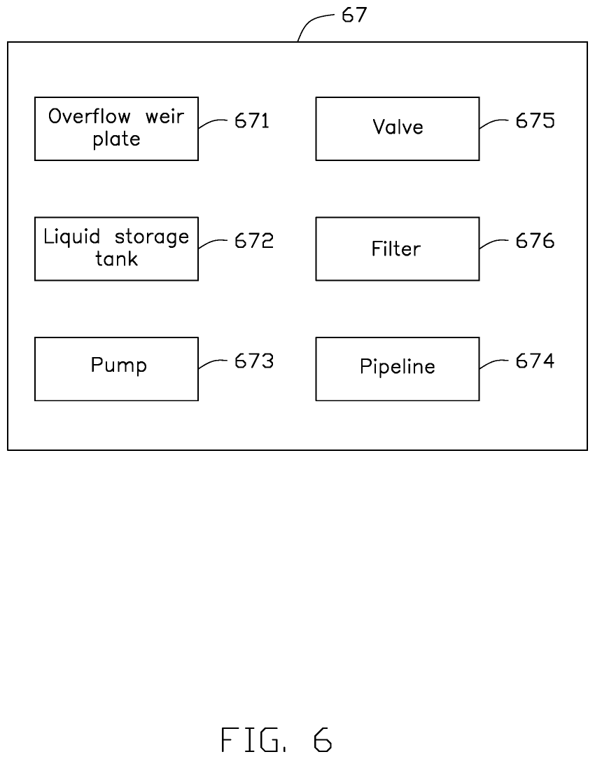

Referring to FIG. 6, the coolant management system 67 includes an overflow weir plate 671, a liquid storage tank 672, a pump 673, a pipeline 674, a valve 675 and a filter 676. The liquid storage tank 672 is separated from the coolant tank by an overflow weir plate 671 at the bottom of the accommodating cavity 101. The pump 673, the pipeline 674, the valve 675 and the filter 676 are disposed inside or outside the box body 10. When the liquid level of the coolant 20 in the accommodating cavity 101 is lower than a preset height, the controller 62 controls the pump 673 to open and the valve 675 to open, and the coolant 20 can be pumped from the liquid storage tank 672, the coolant 20 flows through the filter 676 to the coolant pool at the bottom of the accommodating cavity 101, to keep the coolant level constant, and the excessive pumped coolant flows through the upper end of the overflow weir plate 671 into the liquid storage tank 672.

It can be understood that the number of each of the fan 60, the temperature sensor 63, the humidity sensor 69, the pressure sensor 64, the flow sensor 74, the liquid level sensor 65, the alarm 66, the coolant management system 67, the safety valve 68 and the condenser 40 can be adjusted according to actual needs, and the number can be 1-24, etc.

The two-phase immersion cooling device 100 further includes at least one double-faced sockets 70. The double-faced socket 70 is disposed on the side wall 12. The inner socket of each double-faced socket 70 is exposed to the accommodating cavity 101, and the outer socket of each double-faced socket 70 is exposed to the outside of the box body 10.

The inner socket of the at least one double-faced socket 70 is electrically connected to the fan 60, and the outer socket is connected to the external power supply, so that the fan 60 is electrically connected to the external power supply through the corresponding double-faced socket 70.

The inner socket of the at least one double-faced socket 70 is electrically connected to the heating element 30, the temperature sensor 63, the humidity sensor 69, the pressure sensor 64 and the liquid level sensor 65. The external socket of another double-faced socket 70 is electrically connected to the external connecting lines of the heating element 30, the temperature sensor 63, the humidity sensor 69, the pressure sensor 64, and the liquid level sensor 65, so that the heating element 30, the temperature sensor 63, the humidity sensor 69, the pressure sensor 64 and the liquid level sensor 65 are electrically connected to the external elements. The double-faced socket 70 is hermetically connected to the box body 10 to seal the accommodating cavity 101.

The two-phase immersion cooling device 100 also includes a handle 80, and the handle 80 is disposed on the cover body 15 to facilitate opening the cover body 15.

The two-phase immersion cooling device 100 further includes a supporting member 90, the supporting member 90 is disposed on the bottom of the box body 10, to support the box body 10. The supporting member 90 may be, but is not limited to, a supporting frame to stabilize the box body 10, or a roller to facilitate the movement of the box body 10.

The two-phase immersion cooling device 100 further includes a liquid level window 125, and the liquid level window 125 is disposed on the box body 10. The operation state of the heating element 30 and the liquid level height of the coolant 20 can be observed through the liquid level window 125.

The two-phase immersion cooling device 100 further includes an extracting valve 50, and the extracting valve 50 is disposed on the box body 10.

Before the heating element 30 starts to operate, the vacuum device is used to extract the air or other non-condensable vapor in the accommodating cavity 101 through the extracting valve 50, so as to ensure the efficient condensation and heat transfer operation in the accommodating cavity 101.

The two-phase immersion cooling device 100 further includes a pressure balance valve 73. The pressure balance valve 73 is disposed on the box body 10. The pressure balance valve controller 731 is electrically connected to the controller 62. When the pressure in the accommodating cavity 101 is lower than the atmospheric pressure, in order to facilitate the opening of the cover body, the pressure balance valve 73 can be opened manually or through the controller 62 to make the vapor pressure in the accommodating cavity equal to the atmospheric pressure.

When the user intends to replace, take, assemble, or repair the heating element 30, the fan 60 is first stopped, then the cover body 15 is opened, and the fan 60 leaves the cavity 401 with the opening of the cover body 15. Then, the heating elements 30 can be taken out of the box body 10 or put into the box body 10 through the cavity 401.

Those skilled in the art can understand that the above embodiments are only examples, in which the features of different embodiments can be combined with each other to obtain implementations that are easily conceivable according to the disclosure of the present disclosure but are not clearly indicated in the drawings.

Those skilled in the art should understand that the above description and the embodiments of the present disclosure shown in the drawings are only examples and do not limit the present disclosure. The purpose of the present disclosure has been completely and effectively achieved. The functions and structural principles of the present disclosure have been shown and explained in the embodiments. Without departing from the principles, the implementation of the present disclosure may have any deformation or modification.

What is claimed is:

1. A two-phase immersion cooling device comprising:
a box body comprising a plurality of side walls connected to each other top to bottom, and a bottom wall, the bottom wall is connected to one end of each of the plurality of the side walls, the plurality of the side walls and the bottom wall jointly form an accommodating cavity, and bottom of the accommodating cavity being configured to contain coolant; and a plurality of heating elements disposing in the accommodating cavity and adapted to be immersed in the coolant; a condenser disposing along one or a plurality of the side walls; the condenser is received in the accommodating cavity, is located above the coolant and the heating elements, and is arranged along sidewalls of the tank, an upper cavity surrounded by the condenser is defined; a cover body covering the box body to seal the accommodating cavity; the cover body is expandable on the box body to expose the accommodating cavity to the exterior environment; and wherein at least one fan is fixedly disposed on the cover body and is accommodated in the upper cavity.

2. The two-phase immersion cooling device according to claim 1, wherein: the cover body is detachably or reversibly connected to the box body.

3. The two-phase immersion cooling device according to claim 1, wherein: the two-phase immersion cooling device further comprises a plurality of fans, and the plurality of fans are uniformly disposed in the upper cavity.

4. The two-phase immersion cooling device according to claim 1, wherein: the two-phase immersion cooling device further comprises at least one sensor disposed in the accommodating cavity, wherein at least one sensor comprises at least one of a temperature sensor, a humidity sensor, a pressure sensor, and a liquid level sensor, at least one sensor is configured for sensing at least one of vapor temperature, liquid temperature, vapor humidity, vapor pressure, and liquid level height of the coolant, an inlet temperature, an outlet temperature, and a flow rate of condenser coolant in the accommodating cavity.

5. The two-phase immersion cooling device according to claim 1, wherein: the two-phase immersion cooling device further comprises a controller, an alarm, and a coolant management system, the controller is electrically connected to at least one fan, at least one liquid level sensor, at least one alarm, at least one condensing controller, at least one temperature sensor, at least one pressure sensor, at least one humidity sensor, at least one flow sensor, at least one safety valve controller, at least one pressure balance valve controller; when at least one sensor senses vapor temperature in the accommodating cavity is higher than a preset temperature or vapor pressure in the accommodating cavity is higher than a preset pressure, the controller controls and adjusts vapor volume and vapor pressure of at least one fan and inlet temperature and flow of the coolant in the condenser; when a liquid level height of the coolant detected by the liquid level sensor is lower than a preset height, the controller controls the alarm to output an alarm, and controls the coolant management system to replenish the coolant into the accommodating cavity.

6. The two-phase immersion cooling device according to claim 5, wherein: the liquid level sensor is disposed on the box body, the liquid level sensor is connected to the accommodating cavity, and the liquid level sensor detects a liquid level height of the coolant.

7. The two-phase immersion cooling device according to claim 5, wherein: the coolant management system comprises an overflow weir plate, a liquid storage tank, a pump, a pipeline, a valve, and a filter, in which the pump, the pipeline, the valve, and the filter are disposed inside or outside the box body.

8. The two-phase immersion cooling device according to claim 1, wherein: the plurality of heating elements comprises a server applied to a data center, a battery or an electronic device applied to a new energy vehicle, an electronic chip or a device applied to a home intelligent digital appliance, an electronic chip or an electronic device applied to a digital medical treatment, an electronic chip or electronic device for digital medical treatment, a chip and an electronic device for edge computing, a chip for quantum computing, and a heating components applied to mechanical equipment or electronic equipment.

9. The two-phase immersion cooling device according to claim 1, wherein: at least one fan is a squirrel cage fan, an axial fan, a centrifugal fan, a mixed flow fan, a leafless fan, or a rotating impeller; a driving motor of the at least one fan is a cage induction motor or a wound rotor induction motor, a constant speed motor or a speed regulating motor, or a capacitor starting single-phase asynchronous motor or a capacitor running single-phase asynchronous motor.

10. The two-phase immersion cooling device according to claim 1, wherein: the two-phase immersion cooling device further comprises at least one double-faced socket hermetically disposed on the box body.

11. The two-phase immersion cooling device according to claim 1, wherein: the two-phase immersion cooling device further comprises an extracting valve, wherein the extracting valve is disposed on the box body, the extracting valve is connected to a vacuum device to extract non-condensable vapor in the accommodating cavity.

12. The two-phase immersion cooling device according to claim 1, wherein: the two-phase immersion cooling device further comprises a handle disposed on the cover body.

13. The two-phase immersion cooling device according to claim 1, wherein: the two-phase immersion cooling device further comprises a supporting member, wherein the supporting member is disposed on a bottom of the box body; the supporting member is a supporting frame or a roller.

14. The two-phase immersion cooling device according to claim 1, further wherein: the two-phase immersion cooling device comprises a safety valve, wherein the safety valve is disposed on the box body; when vapor pressure in the accommodating cavity is higher than a preset vapor pressure, the safety valve is opened until the vapor pressure in the accommodating cavity is lower than the preset vapor pressure.

15. The two-phase immersion cooling device according to claim 1, further wherein: the two-phase immersion cooling device comprises a pressure balance valve, the pressure balance valve is disposed on the box body; when vapor pressure in the accommodating cavity is lower than an atmospheric pressure, the pressure balance valve is opened until the vapor pressure in the accommodating cavity is equal to the atmospheric pressure.
